(19) United States
(12) Patent Application Publication
(10) Pub. No.: US 2020/0106419 A1
(43) Pub. Date: Apr. 2, 2020

(54) ELECTRO-ACOUSTIC RF FILTER WITH INCREASED FLANK STEEPNESS, MULTIPLEXER AND METHOD OF DESIGNING AN ELECTRO-ACOUSTIC RF FILTER

(71) Applicant: RF360 EUROPE GMBH, Munich (DE)

(72) Inventors: Joerg HORNSTEINER, Mittenwald (DE); Jakob JAMMER, Munich (DE)

(21) Appl. No.: 16/619,600

(22) PCT Filed: May 17, 2018
(86) PCT No.: PCT/EP2018/062901

§ 371 Date: Dec. 5, 2019

(30) Foreign Application Priority Data
Jun. 14, 2017 (DE) 10 2017 113 152.3

(51) Int. Cl. H03H 9/54; H03H 9/56; H03H 9/70

(52) U.S. Cl. CPC H03H 9/542; H03H 9/70; H03H 9/568

(57) ABSTRACT

An electro-acoustic RF filter allowing improved filter skirts is provided. The filter has a flank between a transmission band and a rejection band and a ladder type like topology. A first inductive element and a second inductive element of the topology are arranged in a respective shunt path and electro-magnetically coupled such that the coupling creates an additional transmission zero.

Electro-acoustic RF filter with increased flank steepness, multiplexer and method of designing an electro-acoustic RF filter

The present invention refers to the field of electro-acoustic filters, in particular to electroacoustic filters with ladder type like topologies.

Electro-acoustic filters employ electroacoustic resonators and allow small spatial dimensions and good filter properties.

In ladder type like filter topologies series resonators are electrically coupled in series in a signal path. Shunt paths electrically connect the signal path to ground. Electro-acoustic resonators can be arranged in shunt paths and in the signal path.

Ladder type filters are known from U.S. Pat. No. 9,019,045.

In modern communication devices a plurality of electrical functions are implemented. To increase data rates more and more frequency bands are used.

Correspondingly, an RF filter is wanted that allows an improved spectral efficiency.

To that end, an electro-acoustic RF filter, a multiplexer comprising such a filter and a method of designing an electro-acoustic RF filter are provided by the claims. Dependent claims provide preferred embodiments.

An electro-acoustic RF filter comprises a first transmission band, a first rejection band and a first flank between the first transmission band and the first rejection band. Further, the electro-acoustic RF filter has a ladder type like topology with one or more electro-acoustic series resonators electrically connected in a signal path. Additionally, the ladder type like topology has a first inductive element connected in a first shunt path between the signal path and ground and a second inductive element connected in a second shunt path between the signal path and ground. The first inductive element and the second inductive element are electro-magnetically coupled such that the coupling creates an additional transmission zero

The additional transmission zero obtained by the coupling between the two inductive elements allows to shape the flank between the rejection and the transmission band such that a steeper band, i.e. an increased skirt steepness, is obtained. Thus, the frequency range in which the transfer function of the filter varies between a small insertion loss in the transmission band and a large insertion loss in the rejection band is reduced. A safety distance between different frequency bands, e.g. for different carriers of WCDMA systems, can be reduced in width and the spectral efficiency is improved.

The transmission band is a frequency range in which the insertion loss is small. The rejection band is a frequency range in which RF signals are strongly suppressed.

It is possible that the transmission band is a pass band of a pass band filter. However, it is possible that the rejection band is a stop band of a band stop filter.

It is possible that one or more shunt paths comprise a shunt resonator which may be an electro-acoustic resonator.

The electro-acoustic RF filter bases on the insight that additional transmission zeros can be created and positioned by the designer of the filter. In particular, it was found that additionally created transmission zeros can be positioned without shifting other existing transmission zeros or resonances.

In this context, a transmission zero is a characteristic frequency of the filter where the transfer function reaches a minimum.

The signal response of an RF filter is represented by a transfer matrix, which can be derived from a network analysis of the RF filter. The transfer function of an RF filter is then obtained by the matrix elements that characterize the signal transmission through the RF filter.

Ladder type like filter topologies are based on basic elements comprising one series resonator and one parallel resonator. A plurality of such basic elements electrically connected in series establish the RF filter. At least for one series resonator and/or at least for one parallel (shunt) resonator, electro-acoustic resonators are used. An electro-acoustic resonator comprises electrode structures and a piezoelectric material. Due to the piezoelectric effect the electrode structures convert between RF signals and acoustic waves. Acoustic energy is confined to the resonator via acoustic reflectors. Such a resonator has a resonance frequency and an anti-resonance frequency. The admittance of the resonator is high at the resonance frequency and low at the anti-resonance frequency.

A band pass filter can be obtained if the characteristic frequencies are chosen such that the resonance frequency of the series resonator mainly coincides with the anti-resonance frequency of the parallel resonator. A band stop filter can be obtained if the anti-resonance frequency of the series resonator mainly coincides with the resonance frequency of the parallel resonator.

In the case of a band pass filter the frequency gap between the resonance frequency and the anti-resonance frequency (pole to zero distance) has an impact on the steepness of the right skirt.

Thus, by providing and shifting the additional transmission zero the steepness of the corresponding flank can be further improved.

This improvement is independent from conventional methods to improve characteristics of the frequency-dependent transfer function such as the use of tuning capacitors or the use of high Q resonators.

Thus, tuning capacitors can be incorporated in parallel to series resonators to further improve filter parameters.

Correspondingly, the use of high Q resonators is also possible to improve the characteristics of the transfer function.

As a consequence of the additionally provided transmission zero more stringent requirements, not only on pass band band-width and insertion loss, but also on isolation (in the case of duplexers) can be complied with. Further, out-of-band suppression and the overall isolation level can be improved. One advantageous application of steeper pass band flanks is, e.g. the transmission frequency band and the reception frequency band of the B3 band.

Correspondingly, it is possible that the transmission zero is positioned in the vicinity<y of the first flank.

It is possible that the filter comprises a second rejection band such that the filter is a band pass filter having a second flank or that the filter further comprises a second transmission band such that the filter is a band rejection filter having a second flank.

As discussed above, in a band pass filter the pass band is arranged between two rejection bands. In a band rejection filter the rejection band is arranged between two pass bands.

Here, the first flank is positioned at a higher frequency than the second flank.

Thus, in the case of a band pass filter the first flank is the flank that limits the pass band against higher frequencies.

It is possible that the number of shunt paths between the first shunt path and the second shunt path is one, two, three, four, five or larger than five.

The terminology “first shunt path” and “second shunt path” is independent from the position of the resonator shunt path within the ladder type like topology. The first shunt path can be arranged at the input port side of the filer, at the output port side of the filter or at any arbitrary position in between.

Correspondingly, the second shunt path can be positioned at the input side terminal of the filter, at the output side terminal of the filter or at an arbitrary in between.

It is possible that the electro-acoustic resonators are selected from SAW resonators (SAW=surface acoustic wave), BAW resonators (BAW=bulk acoustic wave) and GBAW resonators (GBAW=guided bulk acoustic wave).

It is possible that one or more inductive elements are realized as metallized structures in one or more metallized layers in a multilayer carrier substrate.

Electrode structures of the electro-acoustic resonators can be realized and arranged as metallization structures on a surface of a piezoelectric substrate (e.g. in the case of SAW resonators or GBAW resonators). However, electrode structures can also be arranged such that a piezoelectric material is arranged in a sandwich construction between electrode structures (in the case of a BAW resonator). The resonator structures can be arranged at or in dies. The dies can be arranged on a carrier substrate. An electrical connection between dies and the carrier substrate can be arranged by bump connections or by bonding wires. The carrier substrate can comprise one or several dielectric layers, e.g. comprising a ceramic material and one or more metallization layers in which metalized structures establish electrical circuit elements such as inductive elements, capacitive elements or resistive elements or signal lines.

Coupling between the first inductive element and the second inductive element can easily be obtained if the inductive elements are established as structurized metallizations in a multilayer structure. The degree M of the coupling can be adjusted by adjusting the distance between inductive elements. The closer inductive elements are arranged with respect to each other, the larger the coupling factor M.

Inductive elements can be realized as coil structures and a large degree of coupling is obtained if coil structures of the first inductive element and coil structures of the second inductive element are directly arranged one above the other in a multilayer substrate. Alternatively, the coil structures can also be realized in one layer of the substrate in close vicinity to each other. In both cases a horizontal and/or vertical displacement of one inductive element with respect to the other inductive element can be used to set the strength of the electromagnetic coupling.

Thus, a plurality of degrees of freedom in coupling the inductive elements and in choosing the coupling strength M is obtained and a well-suited coupling factor can be easily achieved.

It is possible to construct a multiplexer comprising at least one filter as described above.

Correspondingly, one or more filters can be used in a duplexer, a triplexer, a quadplexer, a quintplexer or a multiplexer of a higher degree.

A method of designing a ladder type like topology is described below. The ladder type like topology has one or more electro-acoustic series resonators electrically connected in a signal path and a first inductive element connected in a first shunt path between the signal path and ground. Further, the topology has a second inductive element connected in a second shunt path between the signal path and ground. The method comprises the steps of:

Establishing an electromagnetic coupling M between the first inductive element and the second inductive element to create an additional transmission zero, and varying the strength of the coupling M such that the additional transmission zero is positioned at a flank.

It is possible to position the additional transmission zero to increase the steepness of an upper pass band filter flank or band rejection filter flank.

The effectiveness of creating an additional transmission zero by establishing an electromagnetical coupling between inductive elements will be recognized by the following quantative thoughts:

In an electric circuit with two inductive shunt elements to ground connected at a first (1) and second (2) terminal the impact of a mutual coupling between two inductors on the relationship between voltages V₁, V₂ and currents I₁ and I₂ are as follows if the strength of the electromagnetic coupling is denoted as M:

V₁=iωL₁I₁−iωMI₂

V₂=−iωMI₁+iωL₂I₂ (1)

Here, L₁ determines the inductance of the first inductive element and L₂ denotes the inductance of the second inductive element.

Using matrix notation the relations according to equations 2 and 3 are obtained.

$$\begin{matrix}( \begin{matrix}{V}_{1} \\ {V}_{2}\end{matrix} ) = ( \begin{matrix}i ω {L}_{1} & - i ω M \\ - i ω M & i ω {L}_{2}\end{matrix} ) ( \begin{matrix}{I}_{1} \\ {I}_{2}\end{matrix} ) & ( 2 ) \\ ( \begin{matrix}{I}_{1} \\ {I}_{2}\end{matrix} ) = \frac{1}{i ω ( {L}_{1} {L}_{2} - {M}^{2} )} ( \begin{matrix}{L}_{2} & M \\ M & {L}_{1}\end{matrix} ) ( \begin{matrix}{V}_{1} \\ {V}_{2}\end{matrix} ) & ( 3 )\end{matrix}$$

In the case of the ladder type like topology, e.g. as shown in FIG. 4, without an electromagnetic coupling voltage current relations are, according to equation 4 showing the admittance matrix.

$$( \begin{matrix}{I}_{1} \\ {I}_{2} \\ {I}_{3}\end{matrix} ) = ( \begin{matrix}{Y}_{1} + \frac{1}{i ω {L}_{1}} & - {Y}_{1} & 0 \\ - {Y}_{1} & {Y}_{1} + {Y}_{2} + i ω {C}_{1} & - {Y}_{2} \\ 0 & - {Y}_{2} & {Y}_{2} + i ω {C}_{2} + \frac{1}{i ω {L}_{2}}\end{matrix} ) ( \begin{matrix}{V}_{1} \\ {V}_{2} \\ {V}_{3}\end{matrix} ) \qquad ( 4 )$$

When—in the case of a topology as shown by FIG. 4—the above-mentioned electromagnetic coupling is introduced, then the admittance matrix becomes the form as shown in equation 5.

Here, Y₁ and Y₂ denote the admittance of the series resonator between the first shunt path and the second shunt path and the series resonator between the second shunt path and the third shunt path, respectively.

This admittance matrix can be simplified as the sum of incoming and outgoing currents at the node between the two series resonators must be zero, as shown in equations 6 and 7.

$$\begin{matrix}( \begin{matrix}{I}_{1} \\ {I}_{2} \\ {I}_{3}\end{matrix} ) = ( \begin{matrix}{Y}_{1} + \frac{1 - {C}_{2} {L}_{2} {ω}^{2}}{i ω {L}_{1} + i {ω}^{3} {C}_{2} ( {M}^{2} - {L}_{1} {L}_{2} )} & - {Y}_{1} & \frac{M}{{L}_{1} / i ω {C}_{2} + i ω ( {L}_{1} {L}_{2} - {M}^{2} )} \\ - {Y}_{1} & {Y}_{1} + {Y}_{2} + i ω {C}_{1} & - {Y}_{2} \\ \frac{M}{{L}_{1} / i ω {C}_{2} + i ω ( {L}_{1} {L}_{2} - {M}^{2} )} & - {Y}_{2} & {Y}_{2} + \frac{i ω {C}_{2} {L}_{1}}{{L}_{1} - {C}_{2} {ω}^{2} ( {L}_{1} {L}_{2} - {M}^{2} )}\end{matrix} ) ( \begin{matrix}{V}_{1} \\ {V}_{2} \\ {V}_{3}\end{matrix} ) & ( 5 ) \\ {I}_{2} = - {Y}_{1} {V}_{1} + ( {Y}_{1} + {Y}_{2} + i ω {C}_{1} ) {V}_{2} - {Y}_{2} {V}_{3} ≡ 0 & ( 6 ) \\ ⇒ {V}_{2} = \frac{{Y}_{1} {V}_{1} + {Y}_{2} {V}_{3}}{{Y}_{1} + {Y}_{2} + i ω {C}_{1}} & ( 7 )\end{matrix}$$

Thus, the admittance matrix becomes:

$$( \begin{matrix}{I}_{1} \\ {I}_{3}\end{matrix} ) = ( \begin{matrix}{Y}_{11} & - \frac{{Y}_{1} {Y}_{2}}{{Y}_{1} + {Y}_{2} + i ω {C}_{1}} + \frac{M}{{L}_{1} / i ω {C}_{2} + i ω ( {L}_{1} {L}_{2} - {M}^{2} )} \\ {Y}_{13} & {Y}_{33}\end{matrix} ) ( \begin{matrix}{V}_{1} \\ {V}_{3}\end{matrix} ) \qquad ( 8 )$$

Matrix element Y₃₁ describing the admittance between the input port and the output port becomes equation 9.

$${Y}_{31} = - ( \frac{{Y}_{1} {Y}_{2}}{\underbrace{{Y}_{1} + {Y}_{2} + i ω {C}_{1}}_{{Y}_{T}}} - \frac{M}{\underbrace{{L}_{1} / i ω {C}_{2} + i ω ( {L}_{1} {L}_{2} - {M}^{2} )}_{{Y}_{coupl}}} ) \qquad ( 9 )$$

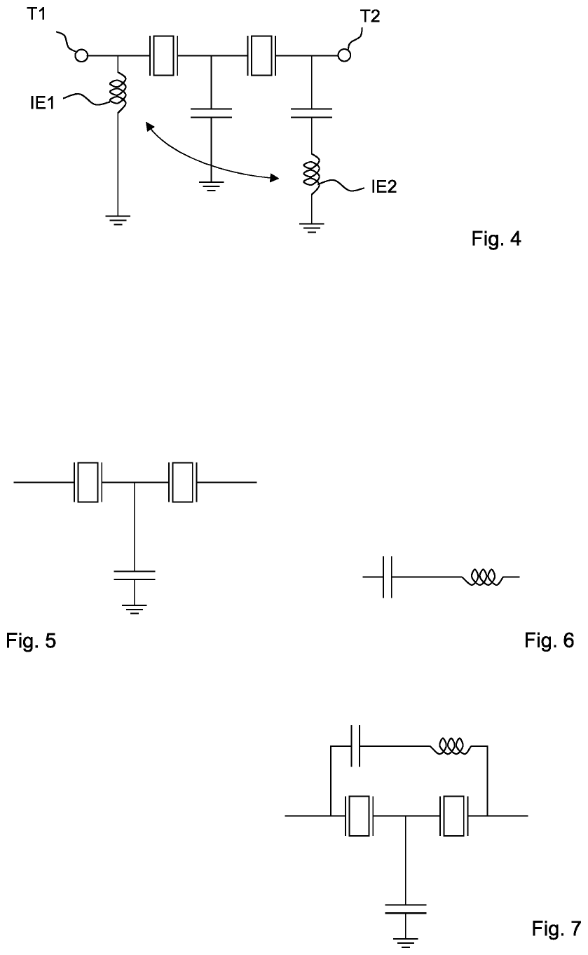

Matrix element Y₃₁ has two components. The left component corresponds to a T-circuit as shown in FIG. 5 while the right component corresponds to a series connection of a capacitive element and an inductive element as shown in FIG. 6.

To quantatively describe the characteristic frequencies such as resonance frequencies and anti-resonance frequencies cases will be regarded where the nominator and the denominator of Y₃₁ are zero. Correspondingly, two frequency values ω₁, ω₂ with maximum admittance (resonances) and one frequency ω₃ with minimum admittance (anti-resonance) are obtained if the electromagnetic coupling M is zero.

For values M being different from zero, frequencies ω₁, ω₂ will be unchanged while anti-resonance frequency ω₃ will be replaced by two anti-resonance frequencies ω₃ and ω₄ as shown by FIGS. 9 and 10.

Thus, the area of the admittance in the vicinity of the anti-resonance is susceptible to improvements by choosing an appropriate coupling strength M.

Further, it is possible to improve the steepness of left filter skirts by using mutual coupling of inductive elements, too, e.g. by applying mutual coupling in one parallel branch.

Further, it is possible to electromagnetically couple three inductive elements.

Inductive elements associated with resonators working at different resonance frequencies are also possible.

Further, electromagnetically coupled inductive elements can be connected to common ground coils.

Basic working principles and details of preferred embodiments are described in the accompanying schematic figures.

In the figures:

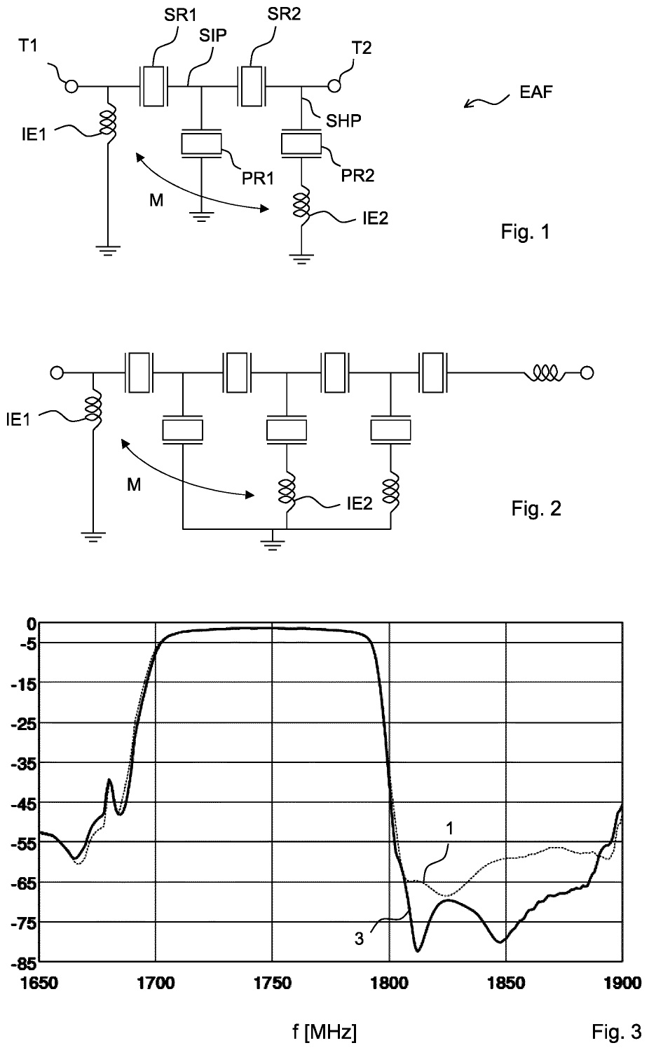

FIG. 1 shows coupled inductive elements;

FIG. 2 shows a second possible topology;

FIG. 3 shows the effect of coupled inductive elements;

FIG. 4 shows a topology according to equations 1 to 9;

FIGS. 5 to 7 show topologies according to equation 9;

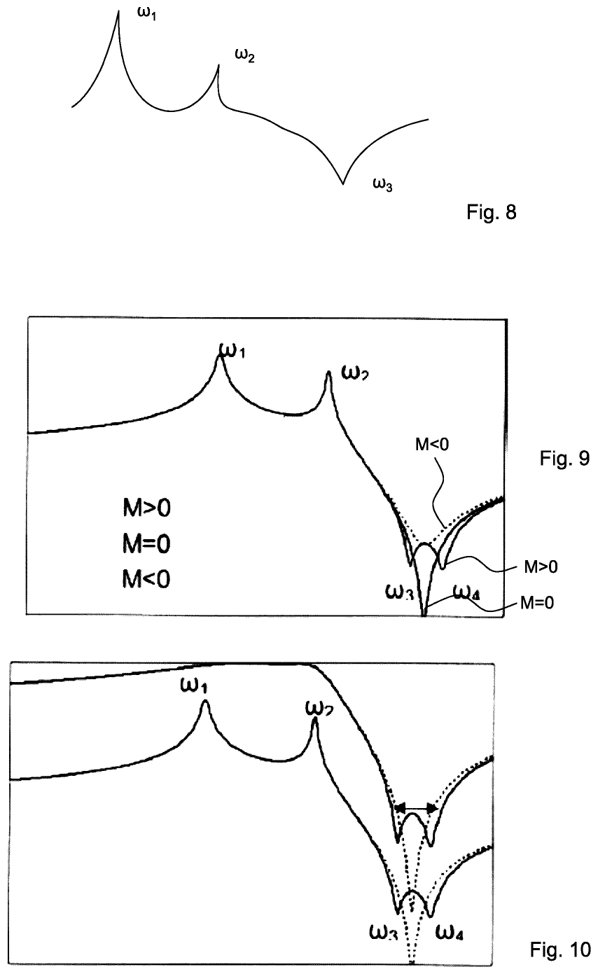

FIG. 8 illustrates possible relations between resonance and anti-resonance frequencies;

FIGS. 9 and 10 show effects of the electromagnetic coupling;

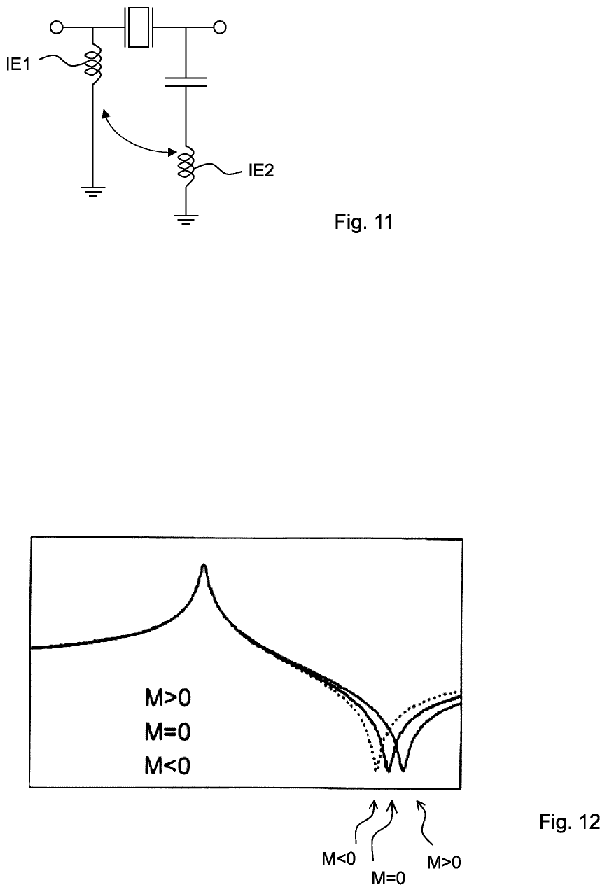

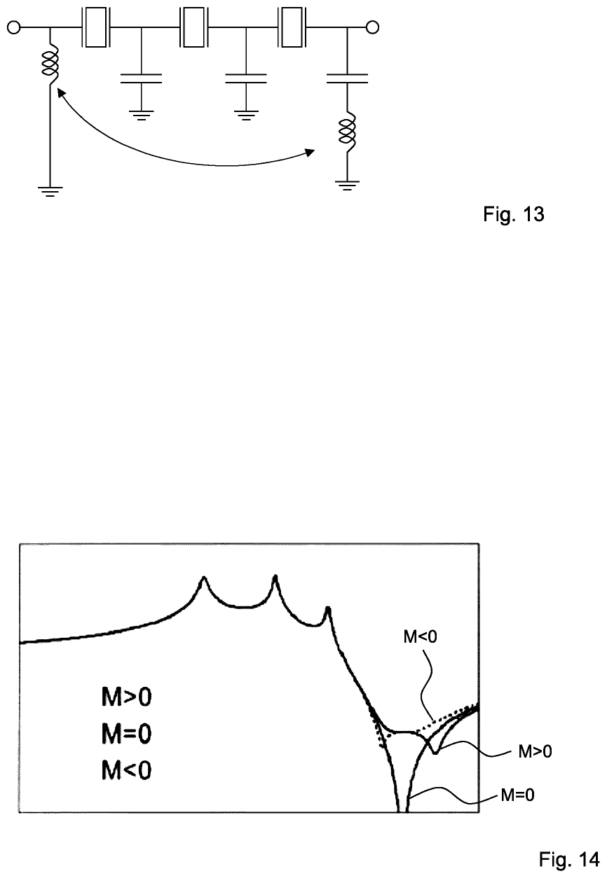

FIGS. 11 and 12 show coupled inductive elements and the effect of coupling in a basic principle;

FIGS. 13 and 14 show coupled inductive elements with two intermediate shunt paths and the corresponding effects,

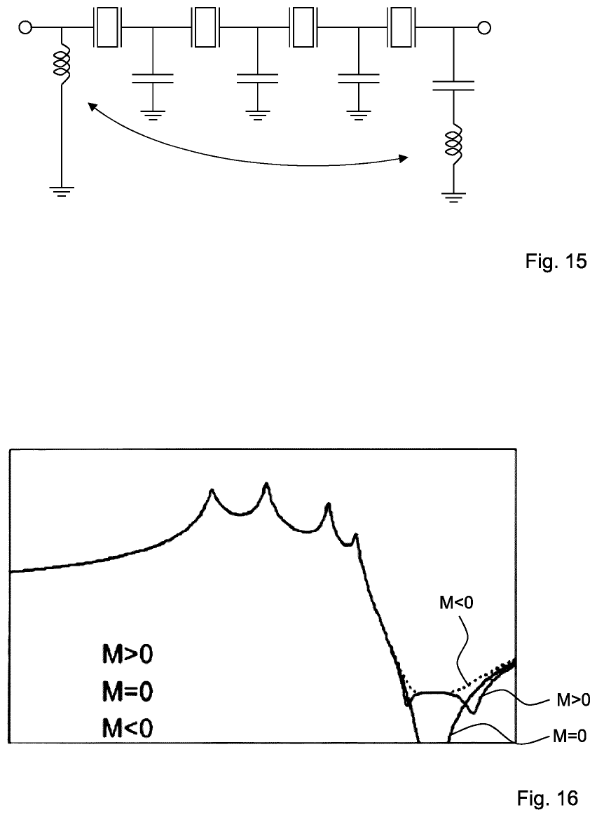

FIGS. 15 and 16 show coupled inductive elements and their effects with three intermediate shunt paths;

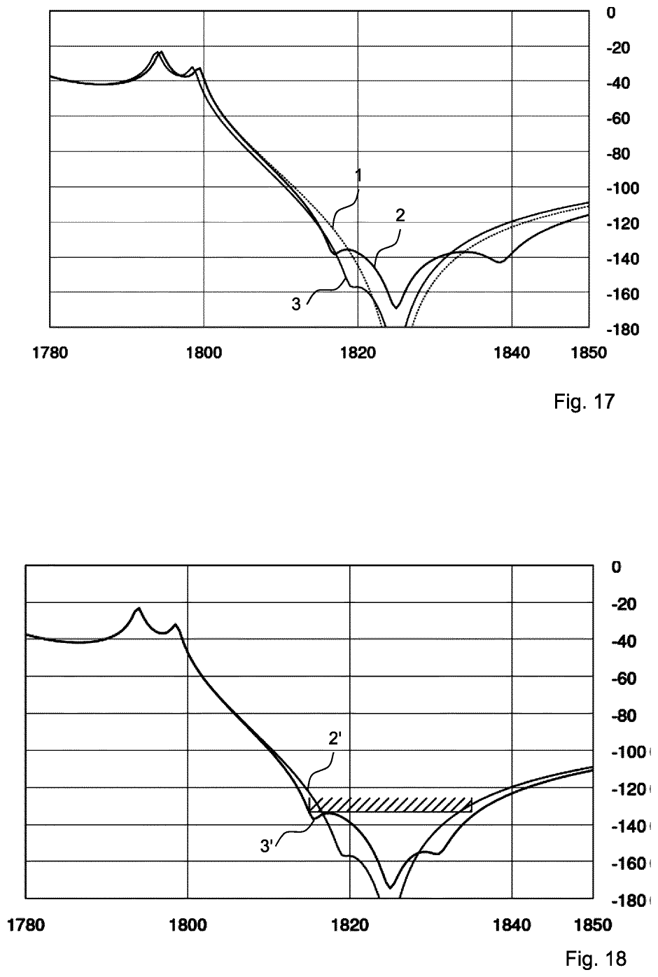

FIG. 17 shows the admittance of a T-section network without coupling (1), with coupling (2) and with improvement by a tuning capacitor (3);

FIG. 18 shows the admittance without coupling (2′) and with coupling and improvement by a tuning capacitor (3′);

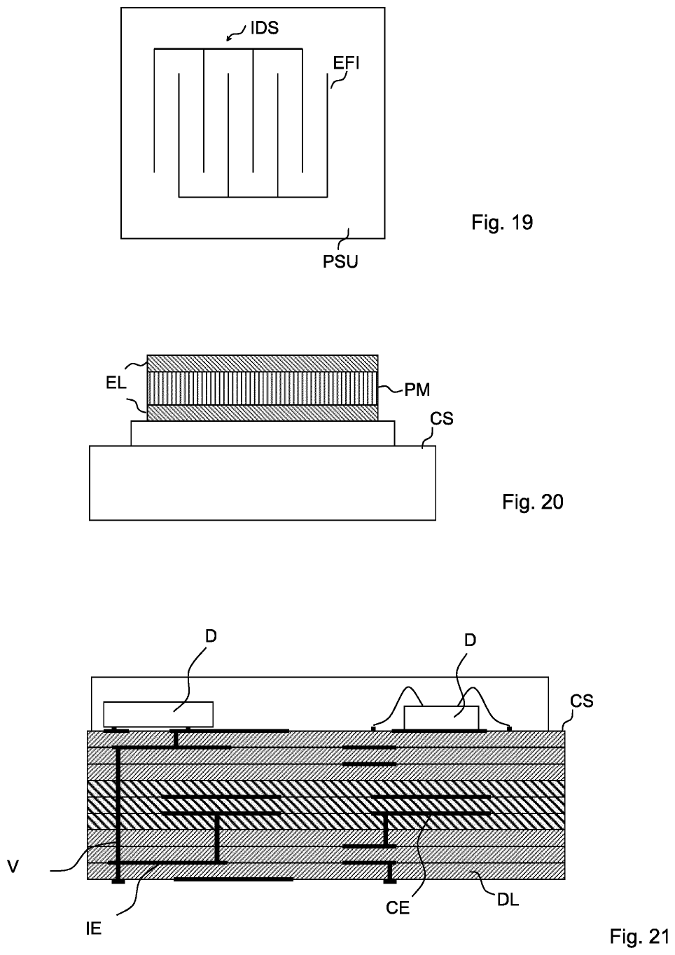

FIG. 19 shows SAW structures;

FIG. 20 shows BAW structure; and

FIG. 21 shows a multilayer carrier substrate.

FIG. 1 shows an equivalent circuit diagram of a possible implementation of electromagnetically coupled inductive elements. In a ladder type like filter topology a signal path SIP is electrically connected between a first terminal T1 and a second terminal T2. The first terminal T1 can be an input terminal and the second terminal T2 can be an output terminal. Within the signal path SIP a first series resonator SR1 and a second series resonator SR2 are electrically connected in series between the first terminal T1 and the second terminal T2. In a first shunt path a first inductive element IE1 is electrically connected between the signal path SIP and ground. In a second shunt path a second inductive element IE2 is electrically connected between the signal path SIP and ground.

In an additional shunt path a first parallel resonator is electrically connected between the signal path and ground. In the second shunt path SHP a second parallel resonator PR2 is electrically connected between the signal path SIP and the second inductive element IE2. The first inductive element IE1 and the second inductive element IE2 are realized such that an electromagnetic coupling M between the two inductive elements is obtained.

The topology is not limited to the topology as shown in FIG. 1. The electro-acoustic filter EAF can also have a structure e.g. as shown in FIG. 2 where a first inductive element IE1 electrically connected to the first terminal T1 and another inductive element IE2 are electrically coupled.

FIG. 3 shows filter transfer functions for a conventional topology as shown in FIG. 2 without an electromagnetic coupling (dashed curve 1) and the filter transfer function for the equivalent circuit diagram shown in FIG. 2, however when an electromagnetic coupling M between the first inductive element IE1 and the second inductive element IE2 is considered. It can be clearly seen that skirt steepness is improved and the out-of-band rejection in the vicinity of the right pass band flank is significantly improved.

FIG. 4 illustrates a simplified topology comprising two series resonators and three shunt paths. The topology of FIG. 4 is the circuit establishing the base for the quantitative considerations as stated in equations 1 to 9.

The effect of the electromagnetic coupling between the first inductive element IE1 and the second inductive element IE2 is such that the circuit behaves as if the series resonators were shunted by a series connection of a capacitive element and an inductive element where the capacity and the inductivity are negative values when M>0.

FIGS. 8 to 10 show the effects of the electromagnetic coupling with respect to the admittance Y₃₁: anti-resonance ω₃ is split into two anti-resonances allowing a higher degree of freedom in shaping pass band skirts of band pass filters or band rejection filters.

Similarly, FIGS. 11 and 12 show the effect of the electromagnetic coupling in a circuit having one series resonator between an input port and an output port where the input port is shunted by a first inductive element IE1 and the output port is shunted by to ground by a series connection of a capacitor and the second inductive element IE2. Depending on the value of the coupling (M<0, M=0, M>0) the frequency position of the anti-resonance is shifted while the frequency position of the resonance is unchanged. In particular, for coupling factors M being smaller than zero, the frequency of the anti-resonance is shifted to lower frequencies towards the resonance frequency decreasing the pole zero distance for increased flank steepness.

FIGS. 13 and 14 illustrate the effect wherein inductive elements connected to the input terminal and to the output terminal, respectively, are electromagnetically coupled while three series resonators and two shunt paths are arranged between the terminals. The frequency position of three resonances is unchanged. Remarkably, no additional transmission zero is created by the coupling, neither for negative nor for positive coupling.

Similarly, FIGS. 15 and 16 show the effect of an electro-magnetic coupling between two inductive elements in a ladder type like circuit topology having five shunt paths.

FIG. 17 shows the admittance of a ladder type like circuit topology without any further means to improve a pass band steepness (dashed curve 1). Curve 3 shows the admittance when an additional tuneable capacitor is used to improve the transmission characteristics of the corresponding filter (curve 3). However, the best result is obtained (curve 2) with coupled inductive elements as described above.

FIG. 18 shows the effects of an additional parallel capacitor (curve 2′) compared having the additional capacitor in combination with mutually coupled coils (curve 3′). Unlike the additional capacitor the coupled inductors can comply with stringent requirements.

FIG. 19 illustrates SAW or GBAW components comprising interdigitated structures IDS where electrode fingers EFI are arranged on a piezoelectric substrate PSU.

FIG. 20 illustrates a cross-section through a sandwich construction of a BAW component. A piezoelectric material PM is sandwiched between two electrodes EL. The sandwich construction can be arranged on a carrier substrate CS. Between the carrier substrate and the sandwich construction an acoustic mirror or cavity can be provided to confine acoustic energy to the resonator.

FIG. 21 illustrates the possibility of integrating circuit elements such as capacitive elements CE or inductive elements IE as metallization structures in metallization layers in a multilayer carrier substrate. The Wire connection W can establish electrical connections between different levels of the substrate. Metallization layers are arranged between different dielectric layers DL of the carrier substrate.

Dies can be arranged in a flip-chip configuration or can be electrically connected to circuit elements via bonding wires.

### LIST OF REFERENCE SIGNS

CS: carrier substrate

D: die

DL: dielectric layer

EAF: electro-acoustic filter

EFI: electrode finger

EL: electrode

IDS: interdigitated structure

IE1, IE2: first, second inductive element

M: electromagnetic coupling

PM: piezoelectric material

PR1, PR2: first, second parallel resonator

PSU: piezoelectric substrate

SHP: shunt path

SIP: signal path

SR1, SR2: first, second series resonator

T1: first terminal

T2: second terminal

W: wire ω₁, ω₂: resonance frequencies ω₃, ω₄: anti-resonance frequencies

1. An electro-acoustic RF filter (EAF), comprising
a first transmission band, a first rejection band and a first flank between the first transmission band and the first rejection band,
a ladder type like topology with one or more electro-acoustic series resonators (SR) electrically connected in a signal path (SIP), a first inductive element (IE1) connected in a first shunt path (SHP) between the signal path (SIP) and ground, and a second inductive element (IE2) connected in a second shunt path (SHP) between the signal path (SIP) and ground, where
the first inductive element (IE1) and the second inductive element (IE2) are electromagnetically coupled such that the coupling creates an additional transmission zero.

2. The filter of claim 1, where the additional transmission zero is positioned in the vicinity of the first flank.

3. The filter of claim 1, comprising
a second rejection band such that the filter is a band pass filter having a second flank or
a second transmission band such that the filter is a band rejection filter having a second flank.

4. The filter of claim 3, where the first flank is positioned at a higher frequency than the second flank.

5. The filter of claim 1, where the number of shunt paths (SHP) between the first shunt path (SHP) and the second shunt path (SHP) is 1, 2, 3, 4, 5, or larger than 5.

6. The filter of one claim 1, where the electro-acoustic resonators are selected from SAW resonators, BAW resonators and GBAW resonators.

7. The filter of claim 1, where the inductive elements (IE1, IE2) are realized as metallized structures in one or more metallized layers in a multilayer carrier substrate.

8. A multiplexer comprising the filter (EAF) of claim 1 as a band pass filter.

9. A method of designing a ladder type like topology with one or more electro-acoustic series resonators (SR) electrically connected in a signal path (SP), a first inductive element (IE1) connected in a first shunt (SHP) path between the signal path (SIP) and ground, and a second inductive element (IE2) connected in a second shunt path (SHP) between the signal path (SIP) and ground,
the method comprising the steps of
establishing an electromagnetic coupling M between the first inductive element (IE1) and the second inductive element (IE2) to create an additional transmission zero,
varying the strength of the coupling M such that the additional transmission zero is positioned at a flank.

10. The method of claim 9, where the additional transmission zero is positioned to increase the steepness of an upper passband filter flank or band rejection filter flank.
